(19) United States
(12) Patent Application Publication
(10) Pub. No.: US 2015/0214345 A1
(43) Pub. Date: Jul. 30, 2015

(54) DOPANT DIFFUSION BARRIER TO FORM ISOLATED SOURCE/DRAINS IN A SEMICONDUCTOR DEVICE

(71) Applicant: GLOBALFOUNDRIES Inc., Grand Cayman (KY)

(72) Inventors: Jing Wan, Malta, NY (US); Jinping Liu, Ballston Lake, NY (US); Churamani Gaire, Clifton Park, NY (US); Mariappan Hariharaputhiran, Ballston Lake, NY (US); Andy Chih-Hung Wei, Queensbury, NY (US); Bharat V. Krishnan, Mechanicville, NY (US); Cuiqin Xu, Malta, NY (US); Michael Ganz, Clifton Park, NY (US)

(73) Assignee: GLOBALFOUNDRIES Inc., Grand Cayman (KY)

(21) Appl. No.: 14/164,368

(22) Filed: Jan. 27, 2014

(51) Int. Cl. H01L 29/735; H01L 29/66; H01L 29/88; H01L 29/73; H01L 21/306; H01L 29/161; H01L 29/06; H01L 29/51; H01L 21/02; H01L 21/265; H01L 29/78; H01L 29/16

(52) U.S. Cl. CPC H01L 29/735; H01L 29/7848; H01L 29/66977; H01L 29/88; H01L 29/7311; H01L 29/1608; H01L 29/161; H01L 29/0653; H01L 29/51; H01L 21/02529; H01L 21/265; H01L 21/30604; H01L 29/6625; H01L 29/66636; H01L 29/66151

(57) ABSTRACT

Approaches for isolating source and drain regions in an integrated circuit (IC) device (e.g., a metal-oxide-semiconductor field-effect transistor (MOSFET)) are provided. Specifically, the device comprises a gate structure formed over a substrate, a source and drain (S/D) embedded within the substrate adjacent the gate structure, and a liner layer (e.g., silicon-carbon) between the S/D and the substrate. In one approach, the liner layer is formed atop the S/D as well. As such, the liner layer formed in the junction prevents dopant diffusion from the source/drain.

### BACKGROUND

1. Technical Field

This invention relates generally to the field of semiconductors, and more particularly, to approaches used to form isolated source/drains in a semiconductor device.

2. Related Art

A typical integrated circuit (IC) chip includes a stack of several levels or sequentially formed layers of shapes. Each layer is stacked or overlaid on a prior layer and patterned to form the shapes that define devices (e.g., a metal-oxide-semiconductor field-effect transistor (MOSFET)) and connect the devices into circuits. In a typical state of the art complementary insulated gate field-effect transistor (FET) process, layers are formed on a wafer to form the devices on a surface of the wafer. Further, the surface may be the surface of a silicon layer on a silicon on insulator (SOI) wafer. A simple FET is formed by the intersection of two shapes, i.e., a gate layer rectangle on a silicon island formed from the silicon surface layer. Each of these layers of shapes, also known as mask levels or layers, may be created or printed optically through well-known photolithographic masking, developing, and level definition, e.g., etching, implanting, deposition, etc.

Silicon based FETs have been successfully fabricated using conventional MOSFET technology. However, as the MOSFET scales down, source/drain junction dopant diffusion becomes increasingly important. The diffusion of the dopant into the channel can cause extra short channel effect and increase the leakage current. Moreover, the out diffusion of the dopant reduces the dopant concentration and increases the parasitic resistance, which can reduce the ON current.

Furthermore, other semiconductor devices, e.g., bipolar transistors, tunneling FETs, and tunneling diodes need a sharp and tightly confined junction. This imposes challenges on conventional doping and annealing processes, which can cause diffusion of the dopant.

### SUMMARY

In general, approaches for isolating source and drain regions in an integrated circuit (IC) device (e.g., a metal-oxide-semiconductor field-effect transistor (MOSFET) are provided. Specifically, the device comprises a gate structure formed over a substrate, a source and drain (S/D) embedded within the substrate adjacent the gate structure, and a liner layer (e.g., silicon-carbon) between the S/D and the substrate. In one approach, the liner layer is formed atop the S/D as well. As such, the liner layer formed in the junction prevents the source/drain from diffusing into the channel and elsewhere, which is beneficial when forming, e.g., a very shallow junction having a sharp profile.

One aspect of the present invention includes a semiconductor device comprising: a gate structure formed over a substrate; a source and a drain (S/D) embedded within the substrate adjacent the gate structure; and a liner layer between the S/D and the substrate.

Another aspect of the present invention includes a semiconductor device including a dopant diffusion barrier, the semiconductor device comprising: a gate structure formed over a substrate; a source and drain (S/D) embedded within the substrate adjacent the gate structure; and a liner layer between the S/D and the substrate.

Yet another aspect of the present invention includes a method for forming a dopant diffusion barrier in a semiconductor device, the method comprising: providing a gate structure formed over a substrate; and forming a liner layer between the substrate and a source and drain (S/D) embedded within the substrate adjacent the gate structure.

### BRIEF DESCRIPTION OF THE DRAWINGS

These and other features of this invention will be more readily understood from the following detailed description of the various aspects of the invention taken in conjunction with the accompanying drawings in which:

FIG. 1 shows formation of a set of recesses in a substrate of a semiconductor device according to an illustrative embodiment;

FIG. 2 shows formation of a liner layer within the set of recesses in the substrate of the semiconductor device according to an illustrative embodiment;

FIG. 3 shows formation of a source and drain (S/D) and another portion of the liner layer according to an illustrative embodiment;

FIG. 4 shows a shallow implantation to the semiconductor device according to illustrative embodiments;

FIG. 5 shows a semiconductor device with a dopant diffusion barrier according to another illustrative embodiment;

FIG. 6 shows a semiconductor device with a dopant diffusion barrier according to another illustrative embodiment;

FIG. 7 shows a semiconductor device with a dopant diffusion barrier according to another illustrative embodiment; and

FIG. 8 shows a process flow for forming a dopant diffusion barrier in a semiconductor device according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Also, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g., a second layer, wherein intervening elements, such as an interface structure, e.g., interface layer, may be present between the first element and the second element.

As used herein, “depositing” may include any now known or later developed techniques appropriate for the material to be deposited including, but not limited to, for example: chemical vapor deposition (CVD), low-pressure CVD (LPCVD), plasma-enhanced CVD (PECVD), semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

As mentioned above, approaches are disclosed herein for isolating source and drain regions in an integrated circuit (IC) device (e.g., a metal-oxide-semiconductor field-effect transistor (MOSFET). Specifically, the device comprises a gate structure formed over a substrate, a source and drain (S/D) embedded within the substrate adjacent the gate structure, and a liner layer (e.g., silicon-carbon) between the S/D and the substrate. In one approach, the liner layer is formed atop the S/D as well. As such, the liner layer formed in the junction prevents the source/drain from diffusing into the channel and elsewhere, which is beneficial, e.g., when forming a very shallow junction having a sharp profile. This approach can have multiple applications. When applied to a MOSFET, the diffusion barrier reduces the short channel effect and increases the thermal budget tolerance. The barrier diffusion can also be used in other devices, such as bipolar transistor, tunneling devices etc., where a sharp junction is required.

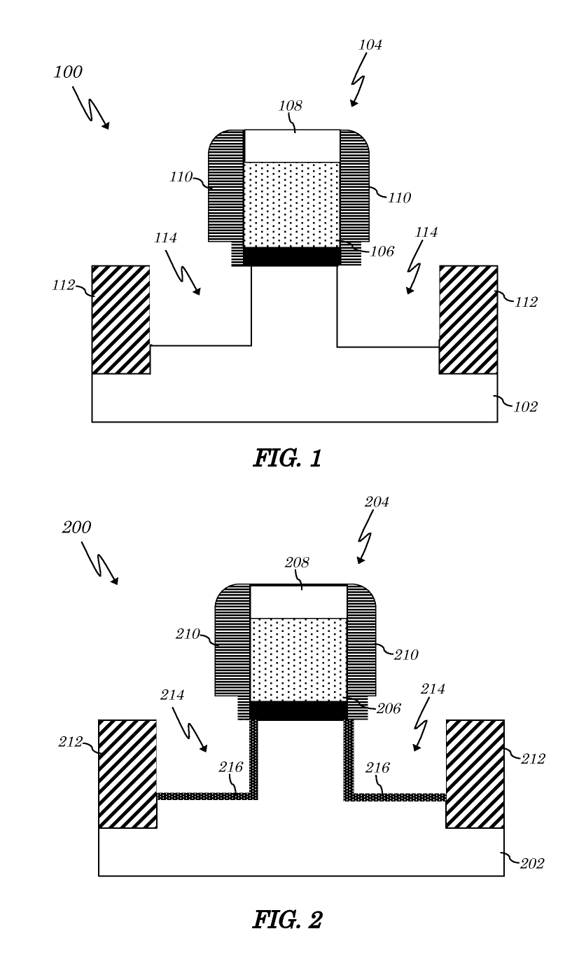

With reference now to the figures, FIG. 1 shows a cross-sectional view of a device 100 (e.g., a MOSFET) according to an embodiment of the invention. Device 100 comprises a substrate 102 (e.g., bulk silicon) and a gate structure 104 formed over substrate 102. Device 100 further comprises a set of shallow trench isolation (STI) regions 112, and a set of recesses 114 formed within substrate 102, e.g., using a silicon recess etch to a desired depth.

Gate structure 104 comprises a gate dielectric 106 (e.g., amorphous-silicon (a-Si)), a nitride cap 108, and a set of spacers 110 adjacent nitride cap 108 and gate dielectric 106. Gate structure 104 may be fabricated using any suitable process including one or more photolithography and etch processes. The photolithography process may include forming a photoresist layer (not shown) overlying device 100, exposing the resist to a pattern, performing post-exposure bake processes, and developing the resist to form a masking element including the resist. The masking element may then be used to etch the various features and layers of gate structure 104, e.g., using reactive ion etch (RIE) and/or other suitable processes.

The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped, or contain doped regions and undoped regions therein. The semiconductor substrate may contain regions with strain and regions without strain therein, or contain regions of tensile strain and compressive strain.

Next, as shown in FIG. 2, a liner layer is 216 formed within recesses 214 to form a barrier layer between subsequently formed S/Ds (not shown) and substrate 202. In one embodiment, liner layer 216 comprises silicon-carbon (SiC) formed within recesses 214 via CVD. As shown, liner layer 216 generally conforms to a bottom surface and inner sidewall surface of each recess 214.

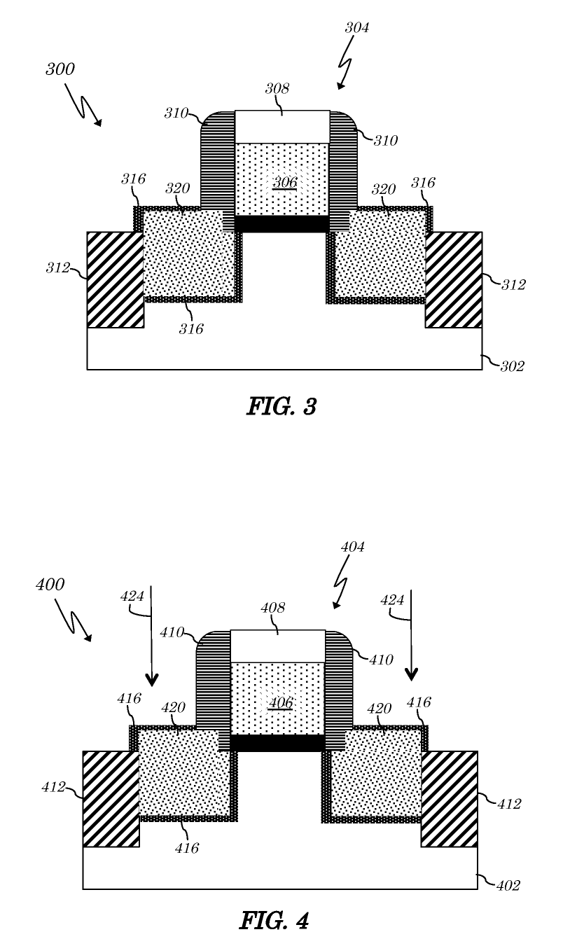

As shown in FIG. 3, a source and drain (S/D) 320 is formed over liner layer 316 within the recesses. In one embodiment, S/D 320 is epitaxially formed using in-situ doping, and comprises P+ doped Silicon Germanium (SiGe) for a p-channel metal-oxide-semiconductor field-effect transistor (PMOSFET) and N+ Silicon carbon (SiC) for a n-channel metal-oxide-semiconductor field-effect transistor (NMOSFET). In an alternative embodiment, S/D 320 comprises undoped Si or SiGe, which may be formed epitaxially, e.g., without in-situ doping.

Liner layer 316 is then formed atop S/D 320. As shown, liner layer 316 is formed to fully envelope S/D 320, which is also bounded by spacers 310 and STI 312. Liner layer 316, which may contain an interstitial carbon, prevents the dopant from diffusing out. Furthermore, the junction profile is better defined by liner layer 316. In this embodiment, liner layer 316 allows a very shallow junction having a sharp profile to be formed.

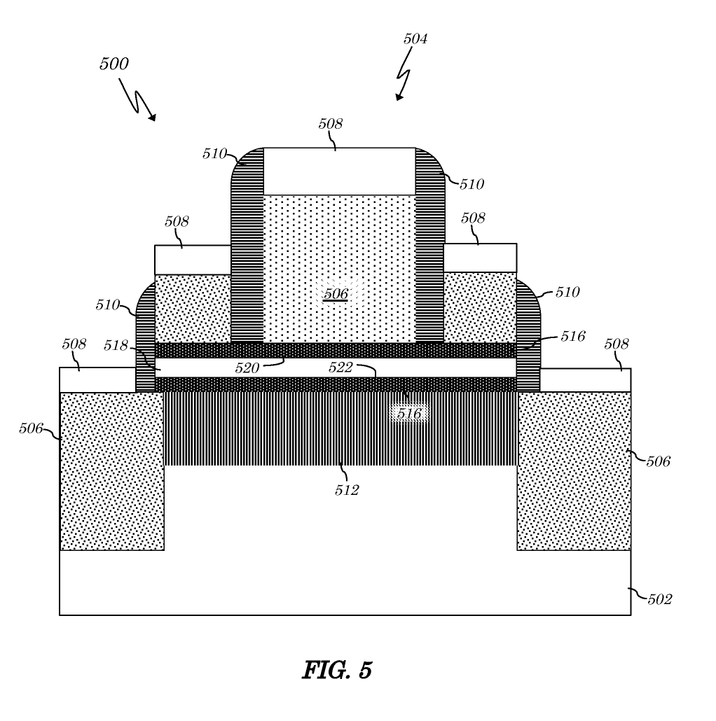

Next, as shown in FIG. 4, device 400 is doped using a shallow implantation 424. However, due to the presence of liner layer 416, diffusion is confined/reduced. Specifically, the carbon dopant in SiC of liner layer 416 occupies the interstitial spot, which is the main diffusion path of the dopant. Therefore, liner layer 416 in the junction of device 400 prevents S/D 420 from diffusing into the channel and elsewhere.

It will be appreciated that the approaches described herein are not limited to a MOSFET. For example, in another embodiment, a diffusion barrier layer is provided within a bipolar junction transistor (BJT) 500, as shown in FIG. 5. Here, BJT 500 comprises a substrate 502, an emitter 504, N+ collectors 506, contacts 508, spacers 510, and a N− doped region 512 of substrate 502. BJT 500 further comprises a base layer 518 (e.g., p-doped SiGe) sandwiched on a top surface 520 and a bottom surface 522 thereof by liner layer 516. As shown, liner layer 516 (e.g., SiC) envelopes base layer 518 to prevent diffusion of dopants.

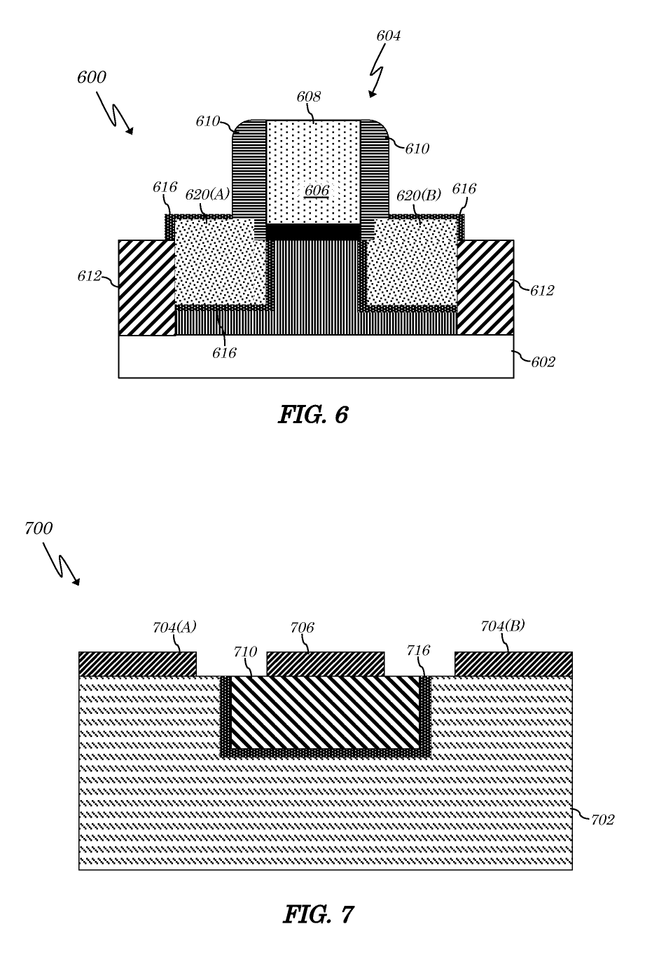

In another embodiment, a diffusion barrier layer is provided within a tunneling FET (TFET) 600, as shown in FIG. 6. TFET 600 includes a substrate 602 (e.g., silicon-on-insulator (SOI)) and a gate structure 604 formed over substrate 602. Gate structure 604 comprises a gate dielectric 606 (e.g., amorphous-silicon (a-Si)), a set of spacers 610 adjacent gate dielectric 606, and a set of shallow trench isolation (STI) regions 612.

TFET 600 further includes a source and drain (S/D) 620(A)-(B) formed over a liner layer 616 within recesses formed within substrate 602. In one embodiment, S/D 620(A) is epitaxially formed using in-situ doping, and comprises a P+ doped material for a p-channel TFET, while S/D 620(B) comprises an N+ material for a n-channel TFET. Liner layer 616 is then formed atop S/D 620. As shown, liner layer 616 is formed to fully envelope S/D 620, which is also bounded by spacers 610 and STI 612. Liner layer 616 also facilitates sharply defined source doping, which allows a high electric field and ON current.

In yet another embodiment, a diffusion barrier layer is provided within a tunneling diode 700, as shown in FIG. 7. Tunneling diode 700 includes a N+ material 702, a set of cathodes 704(A)-(B), an anode 706, and a P+ material 710. As shown, tunneling diode 700 also includes a liner layer 716 between P+ material 710 and N+ material 702. As structured, liner layer 716 (e.g., SiC) envelopes P+ material 710 to prevent diffusion of dopants therefrom. Liner layer 716 also provides a sharply defined P/N junction, which allows a high tunneling current in forward bias.

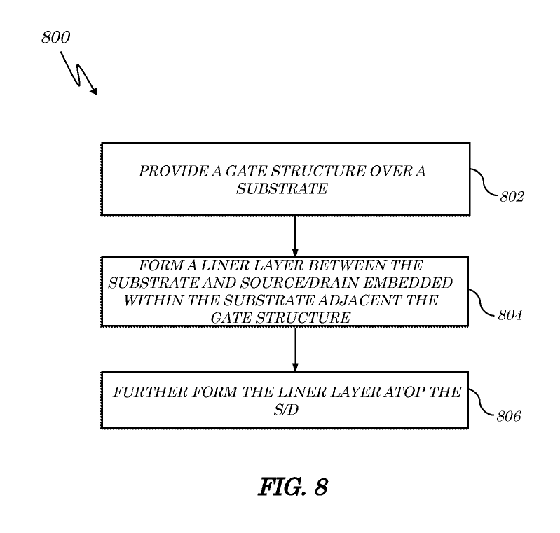

Furthermore, in various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also be comprised of hardware, software, or a combination thereof. Thus, for example, a tool can be a collection of one or more software modules, hardware modules, software/hardware modules, or any combination or permutation thereof, for performing the processing steps shown in FIG. 8. In an exemplary embodiment, the design tool is configured to: provide a gate structure over a substrate (802); and form a liner layer between the substrate and S/D embedded within the substrate adjacent the gate structure (804). In one embodiment, the design tool is further configured to form the liner layer atop the S/D (806) to prevent dopant diffusion therefrom.

As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided an approach for junction isolation in a semiconductor device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor device comprising:
a gate structure formed over a substrate;
a source and drain (S/D) embedded within the substrate adjacent the gate structure; and
a liner layer between the S/D and the substrate.

2. The device of claim 1, wherein the liner layer is further formed atop the S/D.

3. The device of claim 1, further comprising a shallow trench isolation (STI) adjacent the S/D.

4. The device of claim 1, wherein the device comprises one of the following: a metal-oxide-semiconductor field-effect transistor (MOSFET), a tunneling field-effect transistor (TFET), a bipolar junction transistor (BJT), and a tunneling diode.

5. The device of claim 4, wherein the BJT comprises an epitaxial silicon germanium (eSiGe) base, and wherein the liner layer is formed along a top surface and a bottom surface of the eSiGe base.

6. The device of claim 1, the liner layer comprising silicon carbon.

7. The device according to claim 1, wherein the S/D is doped.

8. The device according to claim 1, the gate structure comprising:
an amorphous-silicon (a-Si) gate dielectric;
a nitride cap over the a-Si gate dielectric; and
a set of spacers adjacent the nitride cap and the a-Si gate dielectric.

9. A semiconductor device including a dopant diffusion barrier, the semiconductor device comprising:
a gate structure formed over a substrate;
a source and drain (S/D) embedded within the substrate adjacent the gate structure; and
a liner layer between the S/D and the substrate.

10. The semiconductor device of claim 9, wherein the liner layer is further formed atop the S/D.

11. The semiconductor device of claim 9, further comprising a shallow trench isolation (STI) adjacent the S/D.

12. The semiconductor device of claim 9, wherein the device comprises one of the following: a metal-oxide-semiconductor field-effect transistor (MOSFET), a tunneling field-effect transistor (TFET), a bipolar junction transistor (BJT), and a tunneling diode.

13. The semiconductor device of claim 12, wherein the BJT comprises an epitaxial silicon germanium (eSiGe) base, and wherein the liner layer is formed along a top surface and a bottom surface of the eSiGe base.

14. The semiconductor device of claim 9, wherein the liner layer comprising silicon carbon, and wherein the S/D is doped.

15. A method for forming a dopant diffusion barrier to isolate a source and drain (S/D) in a semiconductor device, the method comprising:
providing a gate structure formed over a substrate; and
forming a liner layer between the substrate and a S/D embedded within the substrate adjacent the gate structure.

16. The method according to claim 15, further comprising forming the liner layer atop the S/D.

17. The method according to claim 15, further comprising etching the substrate to form a set of recesses adjacent the gate structure.

18. The method according to claim 17, the forming the liner layer comprising depositing silicon carbon (SiC) within the set of recesses, wherein the S/D is epitaxially formed over the liner layer within the set of recesses.

19. The method according to claim 16, further comprising doping the semiconductor device using a shallow implantation.

20. The method according to claim 15, the semiconductor device comprising one of the following: a metal-oxide-semiconductor field-effect transistor (MOSFET), a tunneling field-effect transistor (TFET), a bipolar junction transistor (BJT), and a tunneling diode.
